(19) United States
(12) Patent Application Publication
(10) Pub. No.: US 2025/0258367 A1
(43) Pub. Date: Aug. 14, 2025

(54) MIRROR ASSEMBLY FOR MICROMIRROR ARRAY

(71) Applicant: ASML Netherlands B.V., Veldhoven (NL)

(72) Inventors: Peter Pal POLYVAS, Eindhoven (NL); Wilfred Edward ENDENDIJK, Steensel (NL)

(73) Assignee: ASML Netherlands B.V., Veldhoven (NL)

(21) Appl. No.: 18/859,655

(22) PCT Filed: May 24, 2023
(86) PCT No.: PCT/EP2023/063921

§ 371 Date: Oct. 24, 2024

(30) Foreign Application Priority Data
Jul. 12, 2022 (EP) 22184428.5

(51) Int. Cl. G02B 26/08; G03F 7/00

(52) U.S. Cl. CPC G02B 26/0858; G03F 7/70116; G03F 7/7015; G03F 7/70525; G03F 7/706849

(57) ABSTRACT

An assembly for movably supporting a mirror comprises: a mirror; and one or more deformable members. A first end of the or each deformable member defines a support portion and a second end of the or each deformable member is attached (either directly or indirectly to the mirror (for example on a rear surface of the mirror). The or each deformable member comprises a first actuator and a second actuator, the first and second actuators being independently addressable. Actuation of the first actuator moves the mirror relative to the support portion in a first direction and actuation of the second actuator moves the mirror relative to the support portion in a second direction that is opposite to the first direction. In use, the support portion may be attached or fixed to a support and the first and second actuators can be used to move the mirror relative to said support.

### CROSS-REFERENCE TO RELATED APPLICATIONS

This application claims priority of EP application 22184428.5 which was filed on July 12, 2022 and which is incorporated herein in its entirety by reference.

### FIELD

The present invention relates to an assembly, a micromirror array comprising such an assembly, a programmable illuminator comprising such a micromirror array, a lithographic apparatus comprising such a programmable illuminator, an inspection apparatus comprising such a programmable illuminator, a method for forming such an assembly and a method for forming such a micromirror array.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern at a patterning device (e.g., a mask) onto a layer of radiation-sensitive material (resist) provided on a substrate.

The term “patterning device” as employed in this text should be broadly interpreted as referring to a device that can be used to endow an incoming radiation beam with a patterned cross-section, corresponding to a pattern that is to be created in a target portion of the substrate; the term “light valve” can also be used in this context. Generally, the pattern will correspond to a particular functional layer in a device being created in the target portion, such as an integrated circuit or other device. Examples of such patterning devices include: a mask (or reticle); a programmable mirror array; and/or a programmable liquid crystal display (LCD) array, each of which is discussed briefly below.

The concept of a mask (or reticle) is well known in lithography, and it includes mask types such as binary, alternating phase-shift, and attenuated phase-shift, as well as various hybrid mask types. Placement of such a mask in the radiation beam causes selective transmission (in the case of a transmissive mask) or reflection (in the case of a reflective mask) of the radiation impinging on the mask, according to the pattern on the mask. The mask may be supported by a support structure such as a mask table or mask clamp. This support structure ensures that the mask can be held at a desired position in the incoming radiation beam, and that it can be moved relative to the beam if so desired.

One example of a programmable mirror array is a matrix-addressable surface having a viscoelastic control layer and a reflective surface. The basic principle behind such a device is that (for example) addressed areas of the reflective surface reflect incident light as diffracted light, whereas unaddressed areas reflect incident light as undiffracted light. Using an appropriate filter, the undiffracted light can be filtered out of the reflected beam, leaving only the diffracted light behind; in this manner, the beam becomes patterned according to the addressing pattern of the matrix-addressable surface. An alternative embodiment of a programmable mirror array employs a matrix arrangement of tiny mirrors, each of which can be individually tilted about an axis, for example by applying a suitable localized electric field, or by employing electrostatic or piezoelectric actuation means. Once again, the mirrors are matrix-addressable, such that addressed mirrors will reflect an incoming radiation beam in a different direction to unaddressed mirrors; in this manner, the reflected beam is patterned according to the addressing pattern of the matrix-addressable mirrors. The required matrix addressing can be performed using suitable electronic means. In both of the situations described hereabove, the patterning means can comprise one or more programmable mirror arrays. More information on mirror arrays as here referred to can be gleaned, for example, from United States Patents U.S. Pat. Nos. 5,296,891 and 5,523,193, and PCT patent applications WO 98/38597 and WO 98/33096, which are incorporated herein by reference. Such a programmable mirror array may be supported by a support structure such as a frame or table, for example, which may be fixed or movable as required.

An example of a programmable LCD array is given in United States Patent U.S. Pat. No. 5,229,872, which is incorporated herein by reference. Such a programmable LCD array may be supported by a support structure such as a frame or table, for example, which may be fixed or movable as required.

For purposes of simplicity, the rest of this text may, at certain locations, specifically direct itself to examples involving a mask and a mask table; however, the general principles discussed in such instances should be seen in the broader context of the patterning means as hereabove set forth.

To project a pattern on a substrate a lithographic apparatus may use electromagnetic

radiation. The wavelength of this radiation determines the minimum size of features which can be formed on the substrate. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

Besides the wavelength (l) of the radiation and the Numerical Aperture (NA) of the projection lens, the shape, or more generally the angular intensity distribution, of the illumination source is one of the most important parameters in enabling high resolution in lithography.

A micromirror array, comprising an array of hundreds or thousands of micromirrors (often referred to below simply as “mirrors”), can be used in the illumination system of a lithographic apparatus to control the cross-sectional shape and intensity distribution of the light. Each micromirror reflects a spot of light and changing the angles of the micromirrors changes the positions of the spots and thus changes the shape of the radiation beam.

Microelectromechanical systems (MEMS) technology may be used to manufacture and control the mirrors. For example, an electrostatic or piezoelectric MEMS system may be used to angle the mirrors.

Currently micromirror arrays exist for shaping light having a wavelength in the deep ultraviolet spectrum (DUV), e.g. l=193 nm. However, these micromirror arrays cannot be effectively used at shorter wavelengths as required for light in the extreme ultraviolet spectrum (EUV), e.g. l=13.5 nm. New micromirror array technology is required for use with EUV radiation. Also, advantageous new applications for this new micromirror array technology are desired, for use with EUV and/or non-EUV radiation, e.g. visible light or DUV radiation.

It may be desirable and/or may be an aim of the present disclosure to provide an alternative mirror assembly and/or micromirror array that at least partially addresses one or more problems with existing arrangements whether expressly stated herein or otherwise.

### SUMMARY

According to a first aspect of the present disclosure there is provided an assembly comprising: a mirror; and one or more deformable members, a first end of which defines a support portion and a second end of which is attached either directly or indirectly to the mirror; wherein the or each of the one or more deformable members comprises a first actuator and a second actuator; wherein the first and second actuators are independently addressable; and wherein actuation of the first actuator moves the mirror relative to the support portion in a first direction and wherein actuation of the second actuator moves the mirror relative to the support portion in a second direction that is opposite to the first direction.

The assembly according to the first aspect is advantageous, as now discussed. In use, the support portion may be attached or fixed to a support and the first and second actuators can be used to move the mirror relative to said support. The assembly according to the first aspect may be considered to be a microelectromechanical system (MEMS). In some embodiments, in use, a plurality of such assemblies may be provided such that support portions of all of the assemblies are attached or fixed to a common support so as to provide a mirror array. The mirror array may be a micromirror array and may be considered to be a microelectromechanical system (MEMS).

Advantageously, the provision of the first and second actuators in the assembly according to the first aspect, allows both pushing and pulling displacement of the mirror relative to the support via each deformable member. This increases the potential range of rotation of the attached mirror that can be effected.

It will be understood that as used here, the term “actuator” is intended to mean anything that can be actuated to effect relative movement between the mirror and the support portion.

The or each deformable member may comprise a structural frame for supporting an active portion of the first and second actuators.

The structural frame may be of a generally planar configuration. It will be appreciated that, unless stated to the contrary, as used herein an object being of “generally planar configuration” is intended to mean that one of the dimensions of that object is significantly smaller than the other two dimensions of the object.

The first and second actuators of the or each deformable member may be arranged to deform or distort the structural frame so as to achieve relative movement of the mirror and the support portion.

As discussed further below, the active portion of each of the first and second actuators may comprise one or more active layers supported by the structural frame. Furthermore, portions of the structural frame that support those the active portions may form passive portions of the first and second actuators.

The active portions of the first and second actuators may be disposed on the same side of the structural frame.

Advantageously, such an arrangement is simpler and easier to manufacture as the active portions of both the first and second actuators can be applied during a single process step (or two back to back process steps without needing to move or rotate the structural frame in between).

The structural frame may be formed from silicon.

Advantageously, being formed from silicon the structural frame lends resilience and compliance to the assembly.

The structural frame may comprise an array of two or more generally mutually parallel beam portions, each pair of adjacent beam portions connected together at one end, wherein each beam portion is only connected to one adjacent beam portion at any given end.

It will be appreciated that a beam portion is intended to mean an elongate member. As explained above, the structural frame may be of a generally planar configuration. Therefore, each beam portion may also be of a generally planar configuration.

It will be appreciated that as used here a pair of adjacent beam portions being connected together at one end may be achieved by the pair of adjacent beam portions being integrally formed from the same material. A connection portion may be provided between each pair of adjacent beam portions. The connection portion may extend generally perpendicular to an axis of the adjacent beam portions. The connection portion and the pair of adjacent beam portions may be integrally formed from the same material.

Each beam portion is only connected to one adjacent beam portion at any given end. Therefore, for a central beam portion that has two adjacent beam portions, one of the adjacent beam portions is connected to one end of the central beam portion and the other adjacent beam portions is connected to the other end of the central beam portion. With such an arrangement, the beam portions can be generally planar and parallel and by bending one or more of the beam portions at least one end of said bent beam portions can move out of the plane of the (unactuated) structural frame. Furthermore, advantageously, such a geometry lends the deformable member high tip deflection, compliance for its area footprint.

The or each deformable member may comprise: a first beam portion, a first end of the first beam portion defining the first end of the deformable member which defines the support portion; and a second beam portion, a first end of the second beam portion defining the second end of the deformable member which is attached to the mirror, wherein the first and second beam portions are mutually parallel and wherein the second end of the first beam portion is connected to the second end of the second beam portion either directly or indirectly.

With such an arrangement, by distorting or bending the first beam portion and/or the second beam portion (for example using the first and second actuators) the mirror can be moved relative to or each support portion.

In one embodiment, the second end of the first beam portion is connected directly to the second end of the second beam portion such that there are only two beam portions. With such an arrangement, actively bending the first beam portion whilst the second beam portion remains relatively straight (for example less bent than the first beam portion) can move the mirror relative to the support portion in a first direction. Similarly, actively bending the second beam portion (in the same direction) whilst the first beam portion remains relatively straight (for example less bent than the second beam portion) can move the mirror relative to the support portion in a second direction that is opposite to the first direction. When there is no load attached to the support portion(s) of the deformable member(s) when one beam portion is actively bent the other one remains straight. However, if the support portion(s) of the deformable member(s) are connected to, for example a support substrate, then the beam portion that is not actively bent will bend slightly but to a lesser extent than the actively bent beam portion.

In another embodiment, the second end of the first beam portion is connected to the second end of the second beam portion via a central portion of the structural frame, the central portion in turn comprising a plurality of additional mutually parallel beam portions. For such embodiments, each pair of adjacent beam portions may be connected together at one end and each beam portion may only be connected to one adjacent beam portion at any given end.

At least one of the first and second actuators may comprise at least one actuator portion. Each such actuator portion may comprise: a flexible member and an active layer disposed on a surface of said flexible member and operable to distort the flexible member.

Advantageously, as a combination of a flexible member (which may, for example, comprise a beam portion) and an active layer (which may, for example, comprise a piezoelectric material), each actuator portion forms a unimorph actuator capable of deflection.

The active layers of the actuator portions of the first and second actuators may be disposed on the same side of the structural frame.

Advantageously, such an arrangement is simpler and easier to manufacture as the active portions of both the first and second actuators can be applied during a single process step (or two back to back process steps without needing to move or rotate the structural frame in between).

The or each active layer may be configurable in at least a first, nominal state and a second, actuated state.

The first, nominal state may be a state of the active layer with no applied stimulus.

The second, actuated state may be a state of the active layer with an applied stimulus. For example, the second, actuated state may be a state of the active layer under the influence of an applied electric field (or applied voltage). The active layer may either expand or contract to transform from the first state to the second state.

In one embodiment, the active layer expands when transforming from the first state to the second state. For such embodiments, the first state may be referred to as a contracted state and the second state may be referred to as an expanded state.

Such an arrangement allows the or each flexible member (which may, for example, each

comprise a beam portion) to be bent. For example, an active layer may be provided on (for example adhered to) a surface of a flexible member when in the first state. Subsequently, the active layer may be transformed into the second state. This will change a length of the surface of the flexible member on which the active layer is provided relative to an opposite surface and, therefore, the flexible member will bend.

The or each flexible member may comprise a beam portion.

The first actuator may comprise a plurality of actuator portions. The second actuator may comprise a plurality of actuator portions.

For example, the first actuator may comprise a first set of actuator portions provided by a first set of beam portions supporting active layers. The first set of beam portions may comprise every other beam portion (i.e. no pair of adjacent beam portions). The second actuator may comprise a second set of actuator portions provided by a second set of beam portions supporting active layers. The second set of beam portions may comprise the remaining beam portions and may also comprise every other beam portion (i.e. no pair of adjacent beam portions).

The or each active layer may comprise a piezoelectric material.

The piezoelectric material may be Lead Zirconate Titanate.

It will be appreciated that the mirror may comprise a body, which may define a reflective surface. The reflective surface may comprise a multilayer stack (also known as a Bragg mirror). The mirror may be configured to reflect extreme ultraviolet (EUV) radiation. It will be appreciated that the second end of the or each deformable member, which is attached to the mirror, may be attached to a part of the mirror other than the reflective surface. For example, the second end of the or each deformable member may be attached to a surface of the mirror that is opposed to the reflective surface (which surface may be referred to as a rear surface of the mirror).

The or each active layer may comprise material that has a different coefficient of thermal expansion to that of the beam portions and which can be subject to electrothermal actuation.

The assembly may comprise a plurality of deformable members, the second end of at least two of the plurality of deformable members being attached to a different part of the mirror.

Advantageously, this may allow the mirror to be rotatable about a different axis and can limit parasitic motion of the mirror, as now discussed. Parasitic motion may be understood to mean any undesirable non-rotational displacement of the mirror, for example a translational displacement substantially co-planar with the mirror.

For example, in some embodiments the assembly may comprise a pair of deformable members which may be arranged such that the second end of each of the pair of deformable members are attached to different parts of a surface of the mirror that are separated in a first direction. This may allow the mirror to be rotated about an axis that is generally perpendicular to the first direction. In some embodiments the assembly may comprise a second pair of deformable members which may be arranged such that the second end of each of the pair of deformable members are attached to different parts of a surface of the mirror that are separated in a second direction. This may allow the mirror to be rotated about an axis that is generally perpendicular to the second direction.

For embodiments comprising two deformable members, an additional support or hinge may be provided to constrain vertical motion of the mirror and allow for desired rotations.

In some embodiments the assembly may comprise three deformable members which may be arranged such that the second end of each of the three deformable members are attached to different parts of a surface of the mirror, the three points being non-collinear. This may allow the mirror to be rotated about two different axes.

The assembly may comprise four deformable members.

The four deformable members may be arranged in a 4^{th} order rotationally symmetric layout.

Advantageously, a rotationally symmetric arrangement of four deformable elements, means that the natural axes of rotation can pass through the centre of the assembly, and the control signals may be simplified.

The four deformable members may be individually addressable. Each deformable member comprises a first actuator and a second actuator. Therefore, if the four deformable members are individually addressable, the assembly may, in use, receive 8 control signals to control position and/or orientation of the mirror. Alternatively, in some embodiments, the four deformable members may comprise two pairs of opposing deformable members and each pair of opposing deformable members may receive shared control signals such that when one of the pair of deformable members moves up, the opposing deformable member moves down. Advantageously, this can reduce the number of control signals that control the position and/or orientation of the mirror to 4.

The four deformable members may comprise two pairs of opposing deformable members. Each pair of opposing deformable members may be arranged to receive shared control signals.

The shared control signals may be such that when one of the pair of deformable members moves up, the opposing deformable member moves down. Advantageously, this can reduce the number of control signals that control the position and/or orientation of the mirror by a factor of 2.

The or each deformable member may be attached proximally to an outer edge of a reflective surface of the mirror.

As explained above, the second end of the or each deformable member, may be attached to a part of the mirror other than the reflective surface (for example a rear surface of the mirror that is opposed to the reflective surface). It will be appreciated that, the or each deformable member being attached proximally to an outer edge of a reflective surface of the mirror may mean that the or each deformable member is attached to another surface of the mirror at a position that when projected onto the reflective surface of the mirror is proximal to an outer edge of a reflective surface of the mirror.

The support portion of the or each deformable member may be rigid.

The support portions may be formed from silicon dioxide.

The or each deformable member may attache to the mirror by means of one or more pillars.

The or each pillar may be formed from a material with a thermal resistance that is high compared to a thermal resistance of the deformable member which it connects to the mirror.

Advantageously, with such an arrangement the pillars reduce the thermal interface area between the mirror and deformable member, limiting heat transfer from the irradiated mirror to the or each deformable member.

For example, in one embodiment the or each pillar may be formed from silicon dioxide.

The assembly may further comprise a gimbal, a first end of the gimbal being attached to the mirror.

In use, a second end of the gimbal may be attached to a support substrate (for example the same support substrate to which the support portions of the or each deformable member are attached in use). Advantageously, a gimbal may limit relative movement of the mirror and the support substrate to a number of desired configurations, reducing parasitic motion.

According to a second aspect of the present disclosure there is provided a micromirror array comprising: a substrate; and a plurality of assemblies according to the first aspect of the present disclosure; wherein the support portion of each of the one or more deformable members of each of the plurality of assemblies are connected to the substrate.

In use, the substrate may be rigidly fixed to a supporting structure. Advantageously, this means that actuation forces exerted by the actuators of the assemblies cause substantial rotation and/or displacement of the mirrors.

According to a third aspect of the present disclosure there is provided a programmable illuminator comprising: the micromirror array of the second aspect of the present disclosure; a power supply; and a control system, the control system operable to supply control signals using the power supply to the first and second actuators of the one or more deformable members of each of the plurality of assemblies so as to control the orientation of the mirrors of the plurality of assemblies.

That is, the control system may be operable to selectively actuate/energise the first and second actuators (for example piezoelectric elements) to achieve a desired optical configuration of the illuminator.

The control system of the programmable illuminator may control configurations achievable by movements of each mirror about two axes of rotation and a translational displacement. The translational displacement may be substantially normal to the substrate plane.

According to a fourth aspect of the present disclosure there is provided a photolithography apparatus comprising the programmable illuminator of the third aspect of the present disclosure.

According to a fifth aspect of the present disclosure there is provided an inspection or metrology apparatus comprising the programmable illuminator of the third aspect of the present disclosure.

According to a sixth aspect of the present disclosure there is provided a method for forming an assembly, the method comprising: providing a mirror; and providing one or more deformable members, a first end of which defines a support portion, wherein the or each of the one or more deformable members comprises a first actuator and a second actuator and wherein the first and second actuators are independently addressable; attaching a second end of each of the one or more deformable members to the mirror; wherein actuation of the first actuator moves the mirror relative to the support portion in a first direction and wherein actuation of the second actuator moves the mirror relative to the support portion in a second direction that is opposite to the first direction.

The assembly may be an assembly according to the first aspect of the present disclosure.

Providing each of the one or more deformable members may comprise: forming a structural frame comprising two or more beam portions; and depositing an active layer on a surface of at least two of the two or more beam portions.

Forming a structural frame may be achieved using a lithographic process or otherwise.

The or each structural frame may comprise an array of two or more generally mutually parallel beam portions, each pair of adjacent beam portions connected together at one end, wherein each beam portion is only connected to one adjacent beam portion at any given end.

The or each structural frame may comprise: a first beam portion, a first end of the first beam portion defining or proximate to the first end of the deformable member which defines the support portion; and a second beam portion, a first end of the second beam portion defining the second end of the deformable member, wherein the first and second beam portions are mutually parallel and wherein the second end of the first beam portion is connected to the second end of the second beam portion either directly or indirectly.

The method may further comprise connecting an end of each of the one or more structural frames to a rigid support portion.

Attaching a second end of each of the one or more deformable members to the mirror may comprise attaching an end of the structural frame to the mirror via a one or more pillars.

According to a seventh aspect of the present disclosure there is provided a method for forming a micromirror array, the method comprising: providing a substrate; providing a plurality of assemblies according to the first aspect of the present invention; and connecting the support portion of each of the one or more deformable members of each of the plurality of assemblies to the substrate.

It should be understood that the above-described method could be carried out in a number of different sequences, whilst resulting in substantially the same micromirror array.

The step of providing a plurality of assemblies according to the first aspect of the present invention may comprise the method according to the sixth aspect of the present invention.

### BRIEF DESCRIPTION OF THE DRAWINGS

Embodiments of the invention will now be described, by way of example only, with reference to the accompanying schematic drawings, in which:

FIG. 1 depicts a lithographic system comprising a lithographic apparatus and a radiation source;

FIG. 1A depicts a known inspection apparatus;

FIG. 1B depicts a programmable illuminator for use in the inspection apparatus of FIG. 1A;

FIG. 2 schematically depicts an assembly comprising a mirror and one or more deformable members;

FIG. 3A schematically depicts a plan view of a first deformable member that may form part of the assembly shown in FIG. 2 and shown in a first configuration;

FIG. 3B schematically depicts a side view of the deformable member of FIG. 3A in a second configuration;

FIG. 3C schematically depicts a side view of the deformable member of FIG. 3A in a third configuration;

FIG. 4A schematically depicts a plan view of an alternative deformable member that may form part of the assembly shown in FIG. 2 and shown in a first configuration;

FIG. 4B schematically depicts a side view of the deformable member of FIG. 4A in a second configuration;

FIG. 4C schematically depicts a side view of the deformable member of FIG. 4A in a third configuration;

FIG. 5A is a plan view of an assembly generally of the type shown in FIG. 2 comprising a mirror and four deformable members generally of the type shown in FIGS. 4A to 4C;

FIG. 5B is a close perspective view of one deformable member of the assembly of FIG. 5A and its adjacent surroundings;

FIG. 5C is a perspective view of the assembly of FIG. 5A in a possible deflected configuration;

FIG. 6 is a schematic illustration of a method for forming an assembly of the type shown in FIG. 2; and

FIG. 7 is a schematic illustration of a method for forming a micromirror array which may comprise the method shown in FIG. 6.

### DETAILED DESCRIPTION

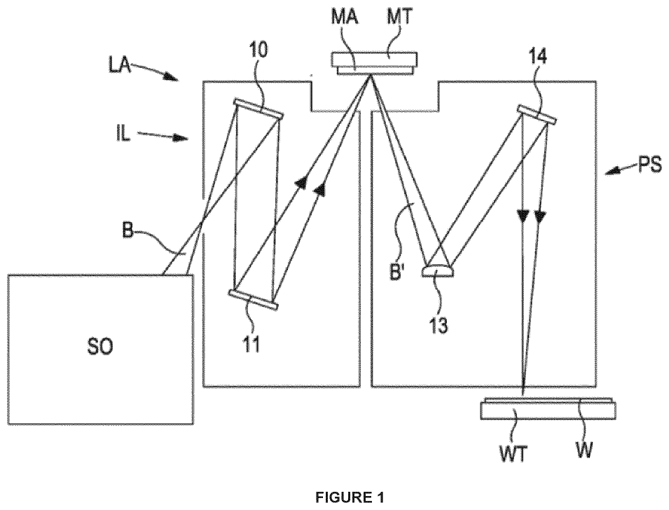

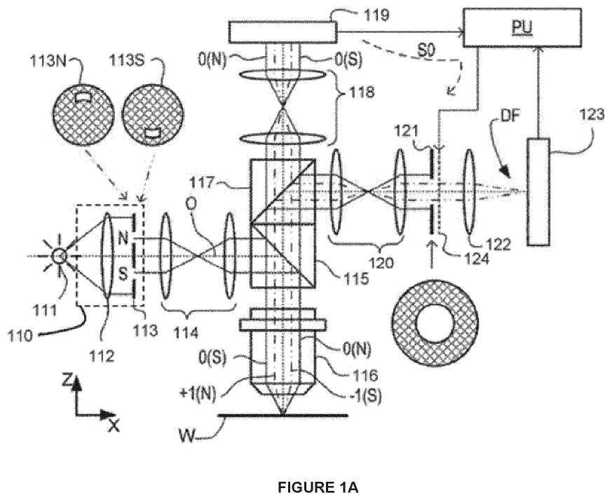

FIG. 1 shows a lithographic system comprising a radiation source SO and a lithographic apparatus LA. The radiation source SO is configured to generate an EUV radiation beam B and to supply the EUV radiation beam B to the lithographic apparatus LA. The lithographic apparatus LA comprises an illumination system IL, a support structure MT configured to support a patterning device MA (e.g., a mask), a projection system PS and a substrate table WT configured to support a substrate W.

The illumination system IL is configured to condition the EUV radiation beam B before the EUV radiation beam B is incident upon the patterning device MA. Thereto, the illumination system IL may include a facetted field mirror device 10 and a facetted pupil mirror device 11. The faceted field mirror device 10 and faceted pupil mirror device 11 together provide the EUV radiation beam B with a desired cross-sectional shape and a desired intensity distribution. The illumination system IL may include other mirrors or devices in addition to, or instead of, the faceted field mirror device 10 and faceted pupil mirror device 11.

After being thus conditioned, the EUV radiation beam B interacts with the patterning device MA. As a result of this interaction, a patterned EUV radiation beam B′ is generated. The projection system PS is configured to project the patterned EUV radiation beam B′ onto the substrate W. For that purpose, the projection system PS may comprise a plurality of mirrors 13,14 which are configured to project the patterned EUV radiation beam B′ onto the substrate W held by the substrate table WT. The projection system PS may apply a reduction factor to the patterned EUV radiation beam B′, thus forming an image with features that are smaller than corresponding features on the patterning device MA. For example, a reduction factor of 4 or 8 may be applied. Although the projection system PS is illustrated as having only two mirrors 13, 14 in FIG. 1, the projection system PS may include a different number of mirrors (e.g. six or eight mirrors).

The substrate W may include previously formed patterns. Where this is the case, the lithographic apparatus LA aligns the image, formed by the patterned EUV radiation beam B′, with a pattern previously formed on the substrate W.

A relative vacuum, i.e. a small amount of gas (e.g. hydrogen) at a pressure well below atmospheric pressure, may be provided in the radiation source SO, in the illumination system IL, and/or in the projection system PS.

The radiation source SO may be a laser produced plasma (LPP) source, a discharge produced plasma (DPP) source, a free electron laser (FEL) or any other radiation source that is capable of generating EUV radiation.

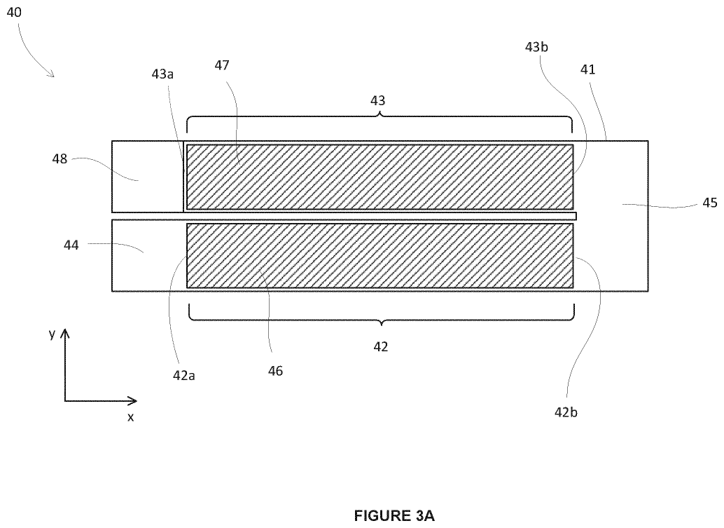

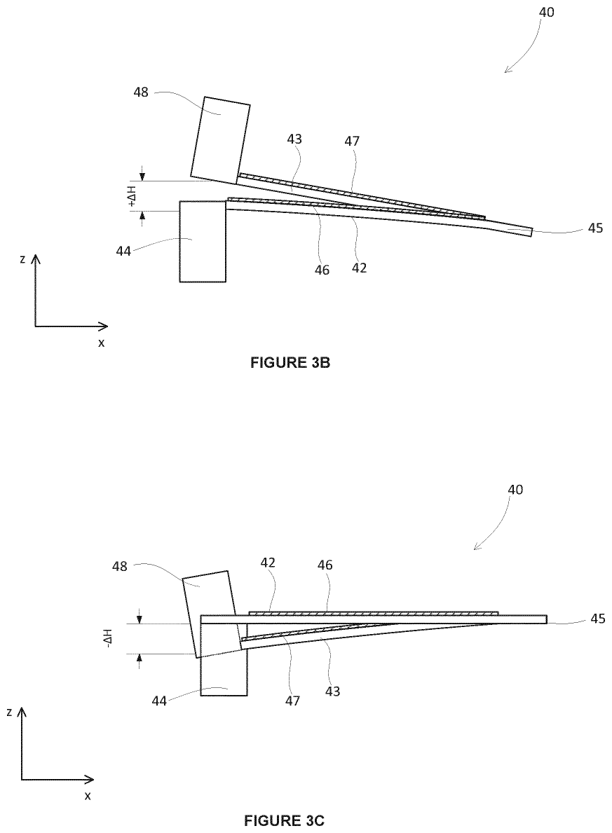

FIG. 1A shows an inspection apparatus that is known from U.S. Pat. No. 9,946,167 B2, which is hereby incorporated in its entirety by reference. FIG. 1A corresponds to FIG. 3a of U.S. Pat. No. 9,946,167 B2. The inspection apparatus is a dark field metrology apparatus for measuring e.g. overlay and or alignment.

In lithographic processes, it is desirable to frequently make measurements of the structures created, e.g., for process control and verification. Various tools for making such measurements are known, including scanning electron microscopes, which are often used to measure critical dimension (CD), and specialized tools to measure overlay, the accuracy of alignment of two layers in a device and alignment, i.e. the position of alignment marks on the substrate. Various forms of scatterometers have been developed for use in the lithographic field. These devices direct a beam of radiation onto a target structure, e.g. a grating or mark(er), and measure one or more properties of the scattered radiation-e.g., intensity at a single angle of reflection as a function of wavelength; intensity at one or more wavelengths as a function of reflected angle; or polarization as a function of reflected angle-to obtain a “spectrum” from which a property of interest of the target can be determined. Determination of the property of interest may be performed by various techniques: e.g., reconstruction of the target structure by iterative approaches such as rigorous coupled wave analysis or finite element methods; library searches; and principal component analysis.

The dark field metrology apparatus shown in FIG. 1A may be a stand-alone device/system or may be incorporated in the lithographic apparatus LA as an alignment system and/or as an overlay measurement system (not shown). An optical axis, which has several branches throughout the apparatus, is represented by a dotted line O. In this apparatus, light emitted by radiation source 111 (e.g., a xenon lamp) is directed onto a substrate W via a beam splitter 115 by an optical system comprising lenses 112, 114 and objective lens 116. These lenses are arranged in a double sequence of a 4F arrangement. Therefore, the angular distribution at which the radiation is incident on the substrate can be selected by defining a spatial intensity distribution in a plane that presents the spatial spectrum of the substrate plane, here referred to as a (conjugate) pupil plane. In particular, this can be done by inserting an aperture plate 113 of suitable form between lenses 112 and 114, in a plane which is a back-projected image of the objective lens pupil plane. In the example illustrated, aperture plate 113 has different forms, labelled 113N and 113S, allowing different illumination modes to be selected. The illumination system in the present example forms an off-axis illumination mode. In the first illumination mode, aperture plate 113N provides an illumination mode that is off-axis in a direction designated, for the sake of description only, as ‘north’. In a second illumination mode, aperture plate 113S is used to provide similar illumination, but which is off-axis in an opposite direction, labelled ‘south’. Other modes of illumination are possible by using different apertures. The rest of the pupil plane is desirably dark, as any unnecessary light outside the desired illumination mode will interfere with the desired measurement signals.

A target structure (not shown), e.g. a grating or mark(er), on substrate W is placed normal to the optical axis O of objective lens 116. A ray of illumination impinging on the target structure from an angle off the axis O gives rise to a zeroth diffraction order ray and two first diffraction order rays. Since the aperture in plate 113 has a finite width (necessary to admit a useful quantity of light) the incident rays will in fact occupy a range of angles, and the diffracted rays 0 and +1/−1 will be spread out somewhat. According to the point spread function of a small target, each order +1 and −1 will be further spread over a range of angles, not a single ideal ray. Note that the grating pitches and illumination angles can be designed or adjusted so that the first order rays entering the objective lens are closely aligned with the central optical axis.

At least the 0 and +1 orders diffracted by the target on substrate W are collected by objective lens 116 and directed back through beam splitter 115. Both the first and second illumination modes are illustrated, by designating diametrically opposite apertures labelled as north (N) and south (S). When the incident ray is from the north side of the optical axis, that is when the first illumination mode is applied using aperture plate 113N, the +1 diffracted rays, which are labelled +1(N), enter the objective lens 116. In contrast, when the second illumination mode is applied using aperture plate 113S, the −1 diffracted rays (labelled −1(S)) are the ones which enter the lens 116.

A second beam splitter 117 divides the diffracted beams into two measurement branches. In a first measurement branch, optical system 118 forms a diffraction spectrum (pupil plane image) of the target on first sensor 119 (e.g. a CCD or CMOS sensor) using the zeroth and first order diffractive beams. Each diffraction order hits a different point on the sensor, so that image processing can compare and contrast orders. The pupil plane image captured by sensor 119 can be used for focusing the inspection apparatus and/or normalizing intensity measurements of the first order beam. The pupil plane image can also be used for many measurement purposes such as reconstruction.

In the second measurement branch, an optical system including lenses 120, 122 forms an image of the target on the substrate W on sensor 123 (e.g. a CCD or CMOS sensor). In the second measurement branch, an aperture plate referred to as field stop 121 is provided in a plane that is conjugate to the pupil-plane. This plane may alternatively be referred to as an ‘intermediate pupil plane’. Field stop 121 functions to block the zeroth order diffracted beam so that the image of the target formed on sensor 123 is formed only from the −1 or +1 first order beam. The images captured by sensors 119 and 123 are output to image processor and controller PU, the function of which will depend on the particular type of measurements being performed. Note that the term ‘image’ is used here in a broad sense. An image of the grating lines as such will not be formed, if only one of the −1 and +1 orders is present.

The illumination system of the inspection apparatus comprises an illuminator 110. As shown in FIG. 1A, this illuminator 110 comprises lens 112 and aperture plate 113. More details of the inspection apparatus can be found in U.S. Pat. No. 9,946,167 B2.

FIG. 1B shows a programmable illuminator 140 for use in the inspection apparatus of FIG. 1A. This programmable illuminator 140 can be used in the inspection apparatus of FIG. 1A instead of the illuminator 110. The programmable illuminator 140 comprises a micromirror array 133 (comprising a plurality of micromirrors 134) as well as a low NA relay 4F system 135 comprising a pair of lenses. Radiation or light from a radiation source 130 (not part of the programmable illuminator 140), e.g. a broad band radiation source or white light source, may be directed via an optional fiber 131 and an optional collimating lens system 132 to the micromirror array 133. A processing unit PU can control the micromirror array 133 in such a way that the micromirrors 134, or more precisely the mirrors in the micromirrors 134, in the micromirror array 133 are tilted individually. By tuning the tilt angle of each individual mirror independently, the spatial distribution of the light that is output by the low NA relay system 135 can be controlled and various illumination modes can be made as desired without having to use aperture plates. If the programmable illuminator 140 is used in the inspection apparatus of FIG. 1A it interfaces with lenses 114, meaning that the light that is output by the low NA relay system 135 is received by the lenses 114 of FIG. 1A.

In order to control the spectral distribution of the light that is output by the low NA relay system 135 at least part of the mirrors may comprise a grating on top of the mirror surfaces (not shown). The grating may be the same for all mirrors or, alternatively, different gratings, e.g. gratings having different pitches, may be used. By appropriate control of the micromirror array 133 the light that is output by the low NA relay system 135 comprises a single wavelength or a single (narrow) range of wavelengths. It is however also possible to control the micromirror array 133 in such a way that the light that is output by the low NA relay system 135 comprises a number of different wavelengths or a number of different (narrow) ranges of wavelengths. The gratings may be lithographically patterned on the mirror surfaces. Each mirror with grating diffracts light of different wavelengths in different directions according to the associated grating equation. A portion of the diffracted light is captured by the low NA relay system 135 and an image is formed. By tuning the angle of each mirror independently, the light distribution at the output can be controlled both spatially and spectrally as (a) certain diffraction order(s) will be captured by the low NA relay system 135 and (an)other diffraction order(s) will not be captured. Such a spatial and spectral light distribution can be used advantageously for example for illuminating and measuring an overlay target structure on a substrate or for measuring the position of an alignment mark on a substrate. In this text, the terms target structure, target, mark, marker and grating are, where the context allows, all synonyms of each other.

The spectral bandwidth of the diffracting beam which can be captured by the low NA relay system 135 is dl=P.NA where P is the pitch of the grating and NA is the numerical aperture of the low NA relay system 135. With P=500 nm and NA=0.02 the spectral bandwidth is 10 nm, meaning that a diffraction order of the grating comprises a range or band of wavelengths of 10 nm.

The spatial resolution of the low NA relay system 135 is ˜λ/NA. With λ=850 nm and NA=0.02 the spatial resolution is 42.5 micrometer. If the size of the mirrors Is greater than 42.5 micrometer, each mirror can be resolved. A reasonable size of a mirror is 100×100 micrometer.

By rotating/tilting the mirrors around their individual axis, a different central wavelength band can be directed into the low NA relay system 135. The rotating range of each mirror required for operation over the visible wavelength range should be Δλ/2P, where Δλ=400 nm for an operating wavelength range of 450 nm-850 nm. This means that each mirror must be able to rotate by 0.4 radians.

Some embodiments of the present disclosure relate to a new assembly for supporting a mirror such that it can be rotated to control an orientation of a reflective surface of the mirror. The mirror may be referred to as a micromirror and the assembly may be considered to be a microelectromechanical system (MEMS). Some embodiments of the present disclosure relate to a micromirror array comprising a plurality of the new assemblies. The mirror array may be a micromirror array and may be considered to be a microelectromechanical system (MEMS). Some embodiments of the present disclosure relate to a lithographic apparatus comprising such a micromirror array. For example, the micromirror array may form part of a lithographic apparatus LA of the type shown schematically in FIG. 1. For example, the faceted field mirror device 10 and/or the faceted pupil mirror device 11 may comprise such a micromirror array. Some embodiments of the present disclosure relate to a programmable illuminator comprising such a micromirror array (for example of the form of the programmable illuminator 140 shown in FIG. 1B). Some embodiments of the present disclosure relate to an inspection and/or metrology apparatus Some embodiments of the present disclosure relate to a programmable illuminator comprising such a micromirror array (for example of the form of the inspection and/or metrology apparatus shown in FIG. 1A) comprising such a programmable illuminator. Some embodiments of the present disclosure relate to a method for forming the new assembly and/or a micromirror array comprising the new assembly.

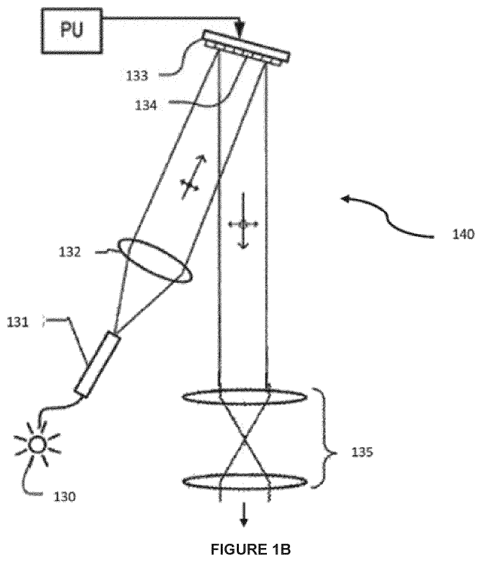

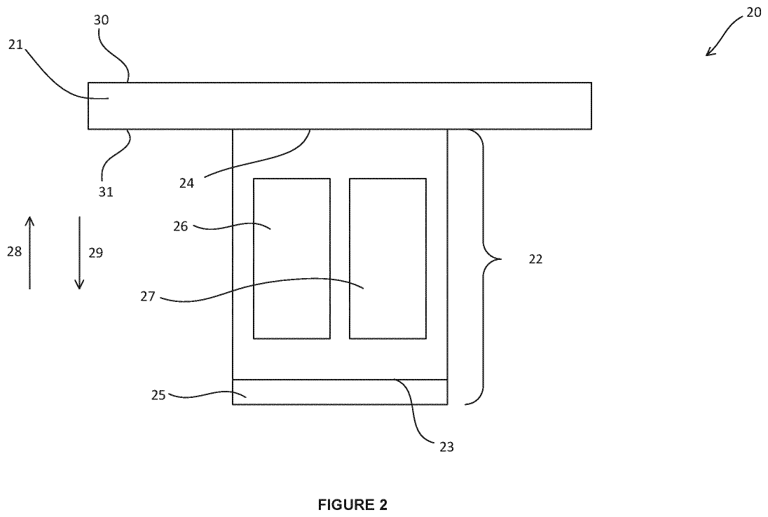

Embodiments of the present disclosure are now described with reference to FIGS. 2 to 7.

FIG. 2 schematically depicts an assembly 20 according to an embodiment of the present disclosure. The assembly 20 of the present invention comprises a mirror 21 and one or more deformable members 22 (only one is shown in FIG. 2). The (or each) deformable member 22 has a first end 23 and a second end 24. The first end 23 defines a support portion 25 of the deformable member 22. The second end 24 of the deformable member 22 is attached the mirror 21 (either directly or indirectly).

The (or each) deformable member 22 comprises a first actuator 26 and a second actuator 27. The first and second actuators 26, 27 are independently addressable. Actuation of the first actuator 26 moves the mirror 21 relative to the support portion 25 in a first direction 28. Actuation of the second actuator 27 moves the mirror 21 relative to the support portion 25 in a second direction 29 that is opposite to the first direction 28. It will be understood that as used here, the term “actuator” is intended to mean anything that can be actuated to effect relative movement between the mirror 21 and the support portion 25.

The assembly 20 shown in FIG. 2 is advantageous, as now discussed. As will be discussed further below, in use, the support portion 25 may be attached or fixed to a support (not shown) and the first and second actuators 26, 27 can be used to move the mirror 21 relative to said support. The assembly 20 may be considered to be a microelectromechanical system (MEMS). In some embodiments, in use, a plurality of such assemblies 20 may be provided such that (the or all of) the support portions 25 of all of the assemblies 20 are attached or fixed to a common support so as to provide a mirror array. The mirror array may be a micromirror array and may be considered to be a microelectromechanical system (MEMS).

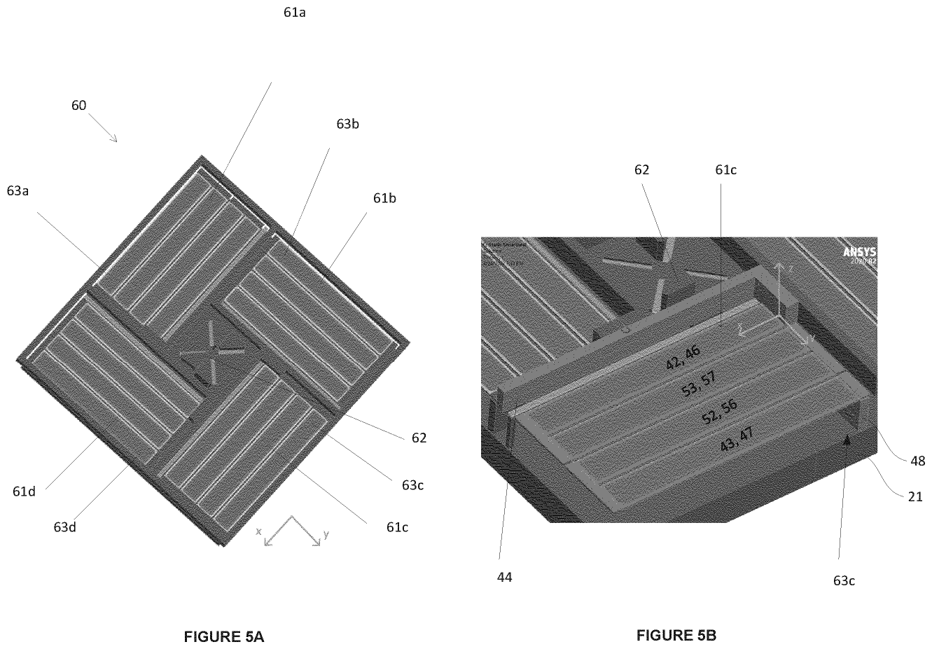

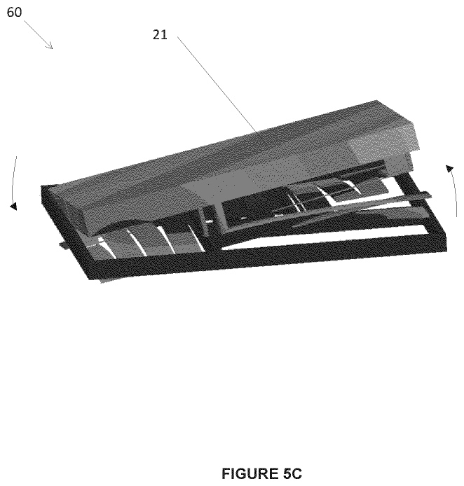

Advantageously, the provision of the first and second actuators 26, 27 in the assembly 20 shown in FIG. 2 allows both pushing and pulling displacement of the mirror 21 relative to the support (to which the support portion(s) 25 are fixed) via each deformable member 22. In particular, the provision of the first and second actuators 26, 27 in the assembly 20 shown in FIG. 2 allows bidirectional movement of the mirror 21 by rotation and/or translation. It will be appreciated that the amount of rotation and translation of the mirror 21 that are achieved will, in general, depend on: (a) how many deformable members 22 are attached to the mirror 21; (b) where the deformable members 22 are attached to the mirror 21 (for example how far from an axis of rotation of the mirror; and (c) whether there are any other constraints on the range of movement of the mirror 21 (for example, in some embodiments, a gimbal may be provided between the mirror 21 and the support portions 25 of the deformable members 22 to limit relative movement therebetween). For example, in some of the embodiments discussed below (see, for example, FIGS. 5A to 5C), if a deformable member 22 is attached to the mirror 21 at a rotation axis of the mirror 21 (for example, if the mirror is constrained by a gimbal) then the mirror 21 may be rotated without significant (net) translation. However, with such embodiments, if the deformable member 22 is attached to the mirror 21 off rotation axis then in general a combination of translation and rotation will result.

The bidirectional movement of the mirror 21 by rotation and/or translation that can be achieved using the first and second actuators 26, 27 in the assembly 20 shown in FIG. 2 increases the potential range of rotation of the attached mirror 21 that can be effected. For embodiments of the assembly 20 comprising a plurality of deformable members 22, by using a symmetric configuration of the deformable members 22 such that a rotation axis of the mirror 21 is disposed between positions at which the deformable members 22 are attached to the mirror 21 can lead to a desirable motion profile. In particular, such an arrangement allows for the orientation of the mirror 21 to be controlled through a range of angles with no or little in-plane translation of the mirror 21. This is particularly advantageous if the assembly 20 is to form part of a mirror array, as now discussed. For example, in use, a plurality of such assemblies 20 may be provided such that the support portions 25 of all of the assemblies 20 are attached or fixed to a common support substrate so as to provide a mirror array. With such an arrangement, it may be desirable to limit any movement of the individual mirrors 21 parallel to a (global or local) plane of the support substrate (which may be referred to as in-plane translation) as such movement may result in adjacent mirrors 21 contacting each other, which is undesirable. Although it may be desirable to limit movement of the individual mirrors 21 parallel to a (global or local) plane of the support substrate movement of the mirrors 21 in a direction that is normal to a (global or local) plane of the support substrate (which may be referred to as a z-direction) may be allowed (and can be achieved with the assembly 20).

It will be appreciated that the mirror 21 may define a reflective surface 30. The reflective surface 30 may comprise a multilayer stack (also known as a Bragg mirror). The mirror 21 may be configured to reflect extreme ultraviolet (EUV) radiation.

It will also be appreciated that the second end 24 of the (or each) deformable member 22, which is attached to the mirror 21, may be attached to a part of the mirror 21 other than the reflective surface 30. For example, as shown schematically in FIG. 2, the second end 24 of the (or each) deformable member 22 may be attached to a surface 31 of the mirror 21 that is opposed to the reflective surface 30 (which surface 31 may be referred to as a rear surface 31 of the mirror 21).

It will be appreciated that the deformable member 22 may have a number of different constructions. A first embodiment of a deformable member 40 (that may be used as the deformable member 22 shown in FIG. 2) is now described with reference to FIGS. 3A to 3C.

FIG. 3A is a schematic plan view of the deformable member 40 in a first configuration, FIG. 3B is a schematic side view of the deformable member 40 in a second configuration; and FIG. 3C shows is a schematic side view of the deformable member 40 in a third configuration.

Deformable member 40 comprises a structural frame 41. The structural frame 41 is of a generally planar configuration (at least when the actuators are not actuated, as explained further below). It will be appreciated that, unless stated to the contrary, as used herein an object being of “generally planar configuration” is intended to mean that one of the dimensions of that object is significantly smaller than the other two dimensions of the object. The dimensions of the structural frame 41 in the z-direction is significantly smaller than the other two dimensions of the object (in the x-y plane).

The structural frame 41 comprises a first beam portion 42 and a second beam portion 43. It will be appreciated that a beam portion is intended to mean an elongate member. As explained above, the structural frame 41 is of a generally planar configuration. Therefore, each of the first and second beam portions 42, 43 are also of a generally planar configuration (at least when an active layer supported thereby is not actuated, as explained further below). The first beam portion 42 extends between a first end 42a and second end 42b. The second beam portion 43 extends between a first end 43a and second end 43b.

The first end 42a of the first beam portion 42 extends from a rigid support portion 44, which defines the support portion 25 of the deformable member 40. The first end 43a of the second beam portion 43 extends from a pillar 48, which defines the second end 24 of the deformable member 40 (which, in use, is attached to the rear surface 31 of the mirror 21, see FIG. 2).

The structural frame 41 of the deformable member 40 is of a generally planar configuration in an unactuated, nominal or unstressed state. However, discussed further below, the structural frame 41 can be distorted out of its nominal plane by actuator portions. The support portion 44 and the pillar 48 are not deformable and have an extent in a direction perpendicular to a nominal plane of the structural frame 41. This extent of the support portion 44 and the pillar 48 in a direction perpendicular to a nominal plane of the structural frame 41 accommodates the deformation of the structural frame 41 and prevents the structural frame 41 from contacting the mirror 21 or a support substrate to which the support portion 44 may be connected.

The first beam portion 42 and the second beam portion 43 are mutually parallel (both extending generally in the x-direction in the Figures). An axis of the beam portions 42, 43 is in the x-direction in this embodiment. The second end 42b of the first beam portion 42 is connected to the second end 43b of the second beam portion 43, forming a profile resembling a Greek capital letter Pi (i.e. Π). It will be appreciated that as used here the first and second beam portions 42, 43 being connected together at one end may be achieved by the pair of adjacent beam portions being integrally formed from the same material, as is the case in this embodiment. A connection portion 45 is provided between the second end 42b of the first beam portion 42 and the second end 43b of the second beam portion 43. The connection portion 45 extends in the y-direction, i.e. generally perpendicular to the axis of the first and second beam portions 42, 43 (the x-direction). The connection portion 45 and the first and second beam portions 42, 43 may be integrally formed from the same material.

Each of the first and second beam portions 42, 43 may be considered to be a flexible member, which forms a passive portion of an actuator, as discussed below. The first and second beam portions 42, 43 support active portions of the actuators, as now discussed.

The deformable member 40 further comprises a first active layer 46 of piezoelectric material disposed on a surface of the first beam portion 42 and a second active layer 47 of piezoelectric material disposed on a surface of the second beam portion 43. The first and second active layers 46, 47 are each configurable in a first contracted state and a second extended state. It will be appreciated that the state of each of the first and second active layers 46, 47 may be controlled by controlling an applied electric field (or applied voltage).

Together, the first beam portion 42 and the first active layer 46 form a first actuator portion, which is equivalent to the first actuator 26 described above. Similarly, the second beam portion 43 and the second active layer 47 form a second actuator portion, which is equivalent to the second actuator 27 described above. Each of these first and second actuators is a unimorph beam.

Each of the first and second active layers 46, 47 allows the beam portion 42, 43 on which it is disposed to be bent. For example, each of the first and second active layers 46, 47 may each be provided on (for example adhered to) a surface of a respective beam portion 42, 43 when in a first state (with no applied field). Subsequently, the active layer may be transformed into the second state using an applied electric field. This will change a length of the surface of the beam portion 42, 43 on which the active layer 46, 47 is provided relative to an opposite surface of that beam portion 42, 43. Under application of an electric field, the piezoelectric active layers expand, whilst the underlying beam portions are unaffected by the electric field. This results in a hogging moment across the actuator portion and deflection of the beam member 42, 43. In the present embodiment, each actuator portion is independently addressable.

Although in this embodiment application of an electric field causes the piezoelectric active layers to expand, it will be appreciated that in other embodiments the piezoelectric active layers may be such that application of an electric field causes the piezoelectric active layers to contract, which would also result in a bending of the beam portions.

Although in this embodiment the first and second active layers 46, 47 comprise a piezoelectric material, it will be appreciated by the skilled person that in alternative embodiments the first and second active layers 46, 47 may be formed from other materials and may deform using different physical mechanisms or phenomena. For example, in one alternative embodiment the first and second active layers 46, 47 may be formed from any material that has a different coefficient of thermal expansion to that of the first and second beam portions 42, 43. With such an arrangement each of the first actuator portion (42, 46) and second actuator portion (43, 47) may be considered to be an electrothermal bimorph to achieve the bending of the first and second actuator portions.

The first and second active layers 46, 47 of piezoelectric material are both disposed on the same side of the structural frame 41 and are independently addressable. Such an arrangement allows second end 43a of the second beam portion 43 (which, in use, is connected to the mirror 21) to be moved relative to the support portion 44: (a) in a first direction when the first active layer 46 is actuated (see FIG. 3B); and (b) in a second direction that is opposite to the first direction when the second active layer 47 is actuated (see FIG. 3C).

When neither of the first and second layers 46, 47 are actuated by an applied field or voltage, the first and second beam portions 42, 43 are generally co-planar (as shown in FIG. 3A). This may be referred to as a nominal, unactuated or unstressed configuration of the structural frame 41.

It should be understood by the term “nominal configuration” is a configuration in which none of the actuator portions are actuated by application of an electric field. As a result, only stresses arising from the load exerted by the mirror weight and self-weight are present in the deformable member 40 in the neutral position.

As illustrated in FIG. 3B, actuating the first active layer 46 results in a hogging deformation of the first beam portion 42. This hogging deformation of the first beam portion 42 is such that the second end 42b of the first beam portion 42 moves in one direction (the negative z-direction in the example shown in FIG. 3B) relative to the first end 42a of the first beam portion 42. The second active layer 47 is not actuated and therefore the second beam portion 43 remains relatively straight and closer to its unstressed configuration. It will be appreciated that, in use, there will be some minor bending of the second beam portion 43 by virtue of its connection to the first beam portion 42 as the first and second beam portions 42, 43 act as two springs in series between two loads (the mirror via pillar 48 and a support substrate via the support portion 44). However, the second beam portion 43 is bent significantly less than the first beam portion 42 (which is actively deformed by the first active layer 46). Because the second ends 42b, 43b of the beam portions 42, 43 are continuously connected to each other (via connection portion 45), the first and second beam portions 42, 43 remain locally mutually tangential at their second ends 42b, 43b (despite the bending of the first beam portion 42). Consequently, the second beam portion 43 extends partially in an opposite direction (the positive z-direction in the example shown in FIG. 3B) as a result of the bending of the first beam portion 42. Therefore, the first end 43a of the second beam portion 43 is moved in the positive z-direction relative to the first end 42a of the first beam portion 42. This may be considered to constitute a ‘push’ configuration.

As illustrated in FIG. 3C, actuating the second active layer 47 results in a hogging deformation of the second beam portion 43. This hogging deformation of the second beam portion 43 is such that the second end 43b of the second beam portion 43 moves in one direction (the negative z-direction in the example shown in FIG. 3C) relative to the first end 43a of the second beam portion 43. The first active layer 46 is not actuated and therefore the first beam portion 42 remains relatively straight and closer to its unstressed configuration. It will be appreciated that, in use, there will be some minor bending of the first beam portion 42 by virtue of its connection to the second beam portion 43 as the first and second beam portions 42, 43 act as two springs in series (the mirror via pillar 48 and a support substrate via the support portion 44). However, the first beam portion 42 is bent significantly less than the second beam portion 43 (which is actively deformed by the second active layer 47). As the first and second beam portions 42, 43 remain locally mutually tangential at their second ends 42b, 43b this bending of the second beam portion 43 results in a deflection of the first end 43a of the second beam portion 43 in the negative z-direction relative to the first end 42a of the first beam portion 42. This may be considered to constitute a ‘pull’ configuration.

The structural frame 41 shown in FIGS. 3A to 3C may be considered to comprise an array of two generally mutually parallel beam portions 42, 43, in which each pair of adjacent beam portions 42, 43 are connected together at one end (the second ends (42b, 43b) and wherein each beam portion 42, 43 is only connected to one adjacent beam portion 42, 43 at any given end.

In this embodiment (as shown in FIGS. 3A to 3C), the second end 42b of the first beam portion 42 is connected directly to the second end 43b of the second beam portion 43 such that there are only two beam portions 42, 43.

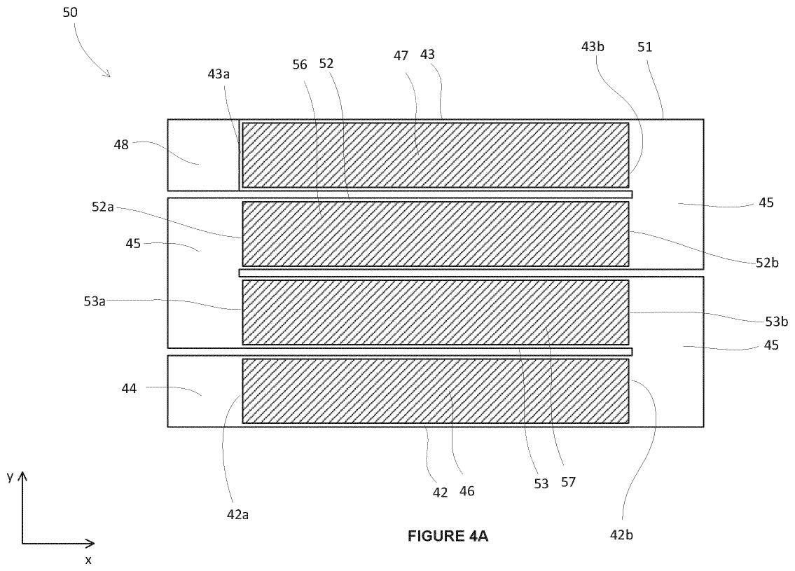

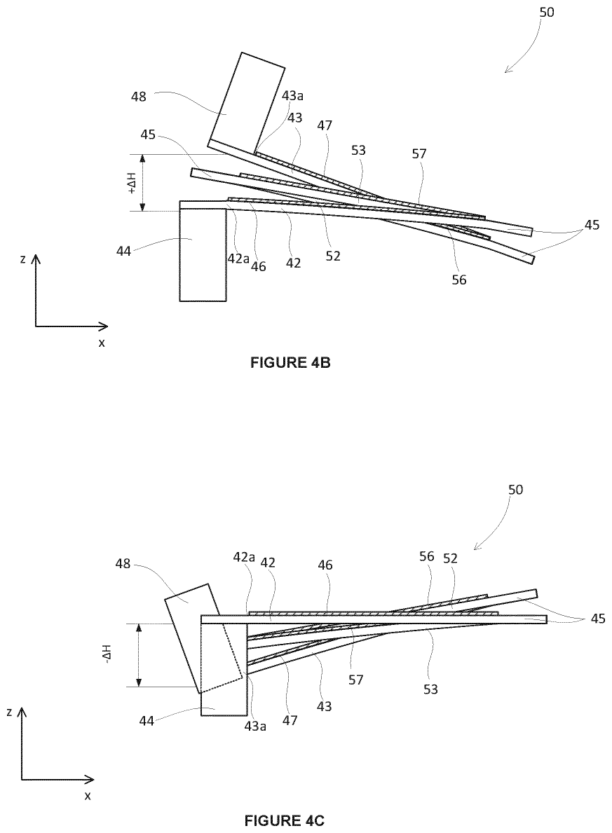

In other embodiments, the second end 42b of the first beam portion 42 may be connected to the second end 43b of the second beam portion 43 via a central portion of the structural frame, the central portion in turn comprising a plurality of additional mutually parallel beam portions. For such embodiments, each pair of adjacent beam portions may be connected together at one end and each beam portion may only be connected to one adjacent beam portion at any given end. An example of such an embodiment is shown in FIGS. 4A to 4C.

A second embodiment of a deformable member 50 (that may be used as the deformable member 22 shown in FIG. 2) is now described with reference to FIGS. 4A to 4C. FIG. 4A is a schematic plan view of the deformable member 50 in a first configuration, FIG. 4B is a schematic side view of the deformable member 50 in a second configuration; and FIG. 4C shows is a schematic side view of the deformable member 50 in a third configuration.

The embodiment of deformable member 50 shown in FIGS. 4A to 4C shares many features in common with the deformable member 40 shown in FIGS. 3A to 3C and described above. Features common to both embodiments of deformable member 40, 50 share common reference numerals. Only the differences will be described in detail below.

As best seen in FIG. 4A, the deformable member 50 is similar in concept to the deformable member 40 shown in FIG. 3A, but having four actuator portions.

The deformable member 50 shown in FIG. 4A comprises a structural frame 51. The structural frame 51 comprises an array of four mutually parallel beam portions 42, 43, 52, 53. As with the embodiment shown in FIGS. 3A to 3C, the first end 42a of the first beam portion 42 extends from a rigid support portion 44, which defines the support portion 25 of the deformable member 50. As with the embodiment shown in FIGS. 3A to 3C, the first end 43a of the second beam portion 43 defines the second end 24 of the deformable member 50 (which, in use, is attached to the rear surface 31 of the mirror 21, see FIG. 2).

In this embodiment, the second end 42b of the first beam portion 42 is connected to the second end 43b of the second beam portion 43 via a central portion of the structural frame 51, the central portion 51 comprising two additional mutually parallel beam portions: a third beam portion 52 and a fourth beam portion 53.

Each pair of adjacent beam portions 42, 43, 52, 53 is connected together at one end. It will be appreciated that as used here a pair of adjacent beam portions being connected together at one end may be achieved by the pair of adjacent beam portions being integrally formed from the same material, as is the case in this embodiment. A connection portion 45 substantially as described above with reference to FIGS. 3A to 3C is provided between each pair of adjacent beam portions 42, 43, 52, 53. The connection portions extend generally in the y-direction, i.e. perpendicular to the axis of the adjacent beam portions 42, 43, 52, 53 (which axis extends in the x-direction). In this embodiment, each connection portion 45 is integrally formed from the same material as the pair of adjacent beam portions 42, 43, 52, 53 that it connects.

Each beam portion 42, 43, 52, 53 is only connected to one adjacent beam portion 42, 43, 52, 53 at any given end. Therefore, for a central beam portion 52, 53 that has two adjacent beam portions, one of the adjacent beam portion is connected to one end of the central beam portion 52, 53 and the other adjacent beam portions is connected to the other end of the central beam portion 52, 53. With such an arrangement, the beam portions 42, 43, 52, 53 can be generally planar and parallel and by bending one or more of the beam portions 42, 43, 52, 53 at least one end of said bent beam portions can move out of the plane of the (unactuated) structural frame 51.

The second end 42b of the first beam portion 42 is connected to a second end 53b of the fourth beam portion 53. A first end 53a of the fourth beam portion 53 is connected to a first end 52a of the third beam portion 52. A second end 52b of the third beam portion 52 is connected to the second end 43b of the second beam portion 43.

The deformable member 50 further comprises a third active layer 56 of piezoelectric material disposed on a surface of the third beam portion 52 and a fourth active layer 57 of piezoelectric material disposed on a surface of the fourth beam portion 53. As with the first and second active layers 46, 47 described above, the third and fourth active layers 56, 57 are each configurable in a third contracted state and a fourth extended state. The state of each of the third and fourth active layers 56, 57 may be controlled by controlling an applied electric field (or applied voltage).

Together, the third beam portion 52 and the third active layer 56 form a third actuator portion. Similarly, the fourth beam portion 53 and the fourth active layer 57 form a fourth actuator portion. Together, the first actuator portion (42, 46) and third actuator portion (52, 56) are equivalent to the first actuator 26 described above with reference to FIG. 2. Similarly, together the second actuator portion (43, 47) and the fourth actuator portion (53, 57) are equivalent to the second actuator 27 described above.

Therefore, in this embodiment, the deformable member 50 comprises four independently addressable unimorph beams/actuator portions (42, 46; 52, 56; 43, 47; 53, 57).

The principle by which unimorph beams deflect was previously described in relation to the deformable member 40 shown in FIGS. 3A to 3C. The same mechanism is in operation for deformable member 50 shown in FIGS. 4A to 4C. In use, the first and third actuator portions (42, 46; 52, 56) are addressed/energised in common and are referred to collectively as a first actuator. Conversely, the second and fourth actuator portions (43, 47; 53, 57) are addressed/energised in common and are collectively referred to as a second actuator.

FIGS. 4B and 4C illustrate the deformable member 50 in a ‘push’ configuration and a ‘pull’ configuration, respectively, illustrating the bidirectional movement (of a mirror 21) that can be achieved using the deformable member 50.

The ‘push’ configuration (FIG. 4B) is actuated by energising the first actuator (42, 46; 52, 56), such that the first and third actuator portions are subject to a hogging deflection. As illustrated in FIG. 4B, actuating the first and third active layers 46, 56 results in a hogging deformation of the first and third beam portions 42, 56. The second and fourth active layers 47, 57 are not actuated and therefore the second and fourth beam portions 43, 53 remain relatively straight and closer to their unstressed configurations. Again, because each pair of adjacent beam portions are continuously connected to each other via a connection portion 45, at this connection portion 45 the pair of adjacent beam portions remain locally mutually tangential. Consequently, the first end 43a of the second beam portion 43 is displaced in the positive z-direction relative to the first end 42a of the first beam portion 42. This may be considered to constitute a ‘push’ configuration.

It can be understood that having two deflected portions (the first and third beam portions 42, 56) results in an increased deflection of the first end 43a of the second beam portion 43 and, advantageously, increases displacement of any attached elements (e.g. a mirror 21).

The pull configuration of FIG. 4C is actuated by energising the second actuator (43, 47; 53, 57), such that the second and fourth actuator portions are subjected to a hogging deflection. As illustrated in FIG. 4C, actuating the second and fourth active layers 47, 57 results in a hogging deformation of the second and fourth beam portions 43, 53 respectively. The first and third active layers 46, 56 are not actuated and therefore the first and third portions 42, 52 remain relatively straight and closer to their unstressed configurations. Again, because each pair of adjacent beam portions are continuously connected to each other via a connection portion 45, at this connection portion 45 the pair of adjacent beam portions remain locally mutually tangential. Consequently, the first end 43a of the second beam portion 43 is displaced in the negative z-direction relative to the first end 42a of the first beam portion 42. This may be considered to constitute a ‘pull’ configuration.

Being of similar configurations, the particulars regarding the construction of the embodiments of FIGS. 3 and 4 are discussed in common.

The active layers of deformable members 40 and 50 may be formed from any suitable material such as, for example, a piezoelectric material. For example, the active layers of deformable members 40 and 50 may be formed from Lead Zirconate Titanate (PZT), a piezoelectric ceramic material. PZT has the property of changing shape under application of an external electric field. In particular, PZT can either expand or contract under application of an external electric field, leading to bending deformation of the beam portions. This allows for the induction of a hogging stress in the unimorph actuator portions. Alternatively, as described above, in one alternative embodiment the active layers 46, 47, 56, 57 may be formed from any material that has a different coefficient of thermal expansion to that of the beam portions 42, 43, 52, 53 that support them. With such an arrangement each actuator portion (42, 46; 43, 46; 52, 56; 53, 57) may be considered to be an electrothermal bimorph and bending of the actuator portion may be achieved via electrothermal actuation.

The structural frames 41, 51 of deformable members 40 and 50 may be formed from any suitable resilient material having reasonable stiffness and ease of fabrication. For example, the structural frames of deformable members 40 and 50 may be formed from silicon. Resilience is especially important as it may be desirable for the structural frames 41, 51 to tolerate many actuation cycles. Compliance is also important, as the deformable members may experience torsional loads in certain configurations. Stiffness is particularly advantageous in this application, as PZT is a poor structural material, so the structural frame 41, 51 supports the active layers 46, 47, 56, 57.

Some embodiments of the new assembly 20 shown in FIG. 2 may comprise a plurality of deformable members 22. The second end 24 of each such deformable member 22 may be attached to a different part of the mirror 21.

Advantageously, this may allow the mirror 21 to be rotatable about a different axis and can limit parasitic motion of the mirror, as now discussed. Parasitic motion may be understood to mean any undesirable non-rotational displacement of the mirror, for example a translational displacement substantially co-planar with the mirror.

For example, in some embodiments the assembly 20 may comprise a pair of deformable members 22 which may be arranged such that the second end 24 of each of the pair of deformable members 22 are attached to different parts of a surface 31 of the mirror 21 that are separated in a first direction. This may allow the mirror 21 to be rotated about an axis that is generally perpendicular to the first direction. In some embodiments the assembly 20 may comprise a second pair of deformable members which may be arranged such that the second end 24 of each of the pair of deformable members 22 are attached to different parts of a surface 31 of the mirror 21 that are separated in a second direction. This may allow the mirror 21 to be rotated about an axis that is generally perpendicular to the second direction.

In some embodiments the assembly 20 may comprise three deformable members 22 which may be arranged such that the second end 24 of each of the three deformable members 22 are attached to different parts of a surface 31 of the mirror 21, the three points being non-collinear. This may allow the mirror 21 to be rotated about two different axes.

FIGS. 5A-C depict an embodiment of an assembly 60 (which is generally of the form of the assembly 20 shown in FIG. 2) comprising four deformable members 61a, 61b, 61c, 61d, each deformable member 61a, 61b, 61c, 61d generally of the form of the deformable member 50 shown in FIGS. 4A to 4C and described above. Component features of each of the deformable members 61a, 61b, 61c, 61d are labelled with the same reference numerals as corresponding component features of the deformable member 50 shown in FIGS. 4A to 4C.

The assembly 60 further comprises a gimbal 62.

As shown in FIG. 5A, the deformable members 61a, 61b, 61c, 61d are attached to the mirror 21 at points 63a, 63b, 63c, 63d respectively such that the total configuration of the deformable members 61a, 61b, 61c, 61d has fourth order rotational symmetry in x-y plane.

In use, the deformable members 61a, 61b, 61c, 61d may be actuated in pairs, preferably one pair being 61a, 61c and another pair being 61b,61d, such that when one deformable member 61a, 61b, 61c, 61d in a pair is in a push configuration and the other is in a pull configuration. The push-pull actuation creates a moment, and hence a rotation about an axis. With reference to the axes provided in FIG. 5A, actuating the pair of deformable members 61a and 61c in the above-described manner would result in a rotation about an axis substantially parallel to the x axis. Actuating a pair of deformable members 61b and 61d in the above-described manner would result in a rotation about an axis substantially parallel to the y axis. Advantageously the mirror 21 can be tilted in plurality of directions by various combinations of the above actuation patterns.

Note that in the assembly 60, the points 63a, 63b, 63c, 63d at which each deformable member 61a, 61b, 61c, 61d is attached to the mirror 21 is proximal to an outer edge of a reflective surface of the mirror 21. As explained above, the second end of the or each deformable member 61a, 61b, 61c, 61d, may be attached to a part of the mirror 21 other than the reflective surface 30 (for example a rear surface 31 of the mirror 21 that is opposed to the reflective surface 30). It will be appreciated that, the or each deformable member 61a, 61b, 61c, 61d being attached proximally to an outer edge of a reflective surface 30 of the mirror 21 may mean that the or each deformable member 61a, 61b, 61c, 61d is attached to another surface 31 of the mirror 21 at a position that when projected onto the reflective surface 30 of the mirror 21 is proximal to an outer edge of a reflective surface 30 of the mirror 21.

FIG. 5B shows a single instance of a deformable member 61c in situ within the assembly 60. It should be understood that the other deformable members and their surrounding elements 61a, 61b, 61d are substantially identically configured.

The second end of the deformable member 61c attaches to the mirror 21 at 63c via its pillar 48. The pillar 48 may be formed from silicon dioxide (SiO₂). This feature reduces the interfacial cross-section between the deformable member 61c and the mirror 21, reducing the heat transfer from the mirror 21 to the deformable member.

FIG. 5C illustrates the configuration resulting from a push-pull actuation of the above-described assembly 60.

Each above-described push-pull actuation defines a natural axis of rotation. Because of the rotationally symmetric arrangement of the four deformable elements 61a, 61b, 61c, 61d, the natural axes of rotation inherently pass through the centre of mirror 21 (in the x-y plane). This minimises unwanted parasitic motion. Parasitic motion can be understood as any undesirable non-rotational displacement of the mirror 21, for example a translational displacement substantially co-planar with the mirror 21.

The gimbal 62 is attached to the mirror 21 and to the support portions 44 of the four deformable elements 61a, 61b, 61c, 61d. In this embodiment, the support portions 44 of the four deformable elements 61a, 61b, 61c, 61d are generally L-shaped in the x-y plane. The support portions 44 of the four deformable elements 61a, 61b, 61c, 61d are all connected so as to form a common support portion that may be mounted to a support substrate.

Parasitic motion is further prevented by the gimbal 62. The gimbal acts as a flexible multidirectional ‘hinge’ restricting the envelope of mirror 21 movement relative to the common support portion provided by the support portions 44 of the four deformable elements 61a, 61b, 61c, 61d.

In addition, the gimbal 62 serves as a conduit for heat flux from the mirror (which is heated by incident radiation), facilitating thermal management of the assembly.

In use, a plurality of the above-described assemblies 20 may be fixed to a common substrate by their support portions 25 so as to form a micromirror array. In use, the substrate may be mounted rigidly to a supporting structure. Advantageously, this means that actuation forces exerted by the actuators 26, 27 of the assemblies 20 cause substantial rotation and/or displacement of the mirrors 21.

The above described micromirror array may form part of a programmable illuminator further comprising a power supply and a control system in communication with the micromirror array. The programmable illuminator is operable (when supplied with power by the power supply) to selectively supply control signals to the first and second actuators 26, 27 of the plurality of deformable members 22, so as to control the orientation configuration of the mirrors 21 of the plurality of assemblies 20. The control system is operable to selectively energise the first and second actuators (for example piezoelectric elements) to achieve a desired optical configuration of the illuminator.

Parasitic motion is particularly disadvantageous when several assemblies are mounted adjacently on a substrate, for example in a micromirror array. It is desirable to restrict an envelope of mirror movement such that the mirrors of each assembly never encroach on the footprint of adjacent assemblies. Should the mirrors encroach on the footprint of adjacent assemblies, mechanical interference between mirrors may occur, resulting in the failure to achieve a desired optical configuration.

Therefore, the above-described characteristics of the assemblies 20 with regard to their inherent envelope of movement is particularly advantageous in a micromirror array which may form part of a programmable illuminator.

Photolithography and inspection and/or metrology apparatus may comprise one or more programmable illuminators of the above-described type.

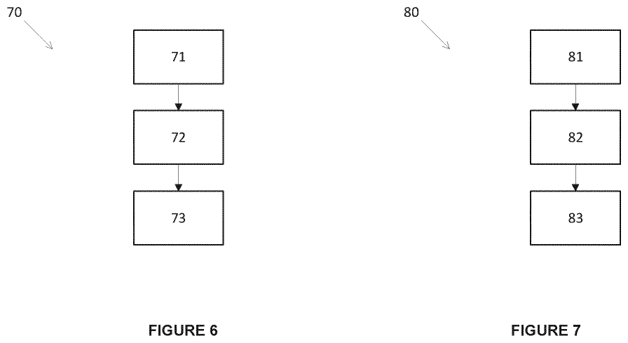

FIG. 6 is a schematic illustration of a method 70 for forming an assembly of the type shown in FIG. 2 and described above.

The method 70 comprises a step 71 of providing a mirror 21. The mirror 21 may comprise a Bragg reflector for EUV radiation.

The method 70 further comprises a step 72 of providing one or more deformable members 22, depending on the desired configuration. A first end 23 of the deformable member 22 defines a support portion 25. The or each deformable member 22 comprises a first actuator 26 and a second actuator 27 and the first and second actuators can be independently addressed or energized.

The deformable members 22 may be generally of the form of the deformable members 40, 50 shown in FIGS. 3A to 3C and 4A to 4C. Step 72 may comprise: forming a structural frame 41, 51 comprising two or more beam portions 42, 43, 52, 53 depositing an active layer 46, 47, 56, 57 on a surface of at least two of the two or more beam portions 42, 43, 52, 53. Forming the structural frame 41, 51 may be achieved using a lithographic process or otherwise. Step 72 may further comprise connecting an end of each of the one or more structural frames 41, 51 to a rigid support portion 44.

The method 70 further comprises a step 73 of attaching the second end 24 of each deformable member 22 to the mirror 21. The second ends 24 of the deformable members 22 may be attached to a rear surface 31 of the mirror 21 via one or more pillars 48.

Optionally, a plurality of assemblies of the above described embodiments and fabricated according to method 70 can be provided along with a substrate. By connecting the support portion of each of the one or more deformable members of each of the plurality of assemblies to the substrate, a micromirror array can be formed.

FIG. 7 is a schematic illustration of a method 80 for forming a micromirror array. The method 80 comprises a step 81 of providing a substrate. The method 80 further comprises a step 82 of providing a plurality of assemblies 20 generally of the form shown in FIG. 2. The method 80 further comprises a step 83 of connecting the support portion 25 of each of the one or more deformable members 22 of each of the plurality of assemblies 20 to the substrate.

It should be understood that the above-described method could be carried out in a number of different sequences, whilst resulting in substantially the same micromirror array.

The step 81 of providing a plurality of assemblies 20 generally of the form shown in FIG. 2 may comprise the method 70 shown in FIG. 6.

It will be appreciated by one of ordinary skill in the art that the invention has been described by way of example only, and that the invention itself is defined by the claims. Numerous modifications and variations may be made to the exemplary design described above without departing from the scope of the invention as defined in the claims. For example, the method steps may be performed in a different order and/or the method may comprise additional method steps.

The structural frames 41 and 51 described above comprise a support portion 44 which is integrally formed with the structural frames 41 and 51. Alternatively, in other embodiments the support portion 44 may be formed separately and subsequently attached a second end of the structural frames 41 and 51. A further possibility would be to provide each assembly with a single support portion in common between multiple deformable members.

It will be appreciated that the gimbal 62 of the assembly 60 shown in FIGS. 5A to 5C is an optional feature and that the gimbal 62 may be omitted from the design with little impact on the mechanical characteristics of the assembly 60. It is notable that such a change would allow translational displacement of the mirror 21, such as a translation normal to a plane of the mirror 21 by actuating all deformable members to push or pull.

Additionally, each assembly 20 may comprise any number of deformable members 22, for example three. The deformable members 22 may also be of a different configuration to that specified in relation to assembly 60, for example the two beam portion embodiment deformable member 30.

In the above described embodiments the assemblies, assembly elements and micromirror array have been described in relation to figures. It should be understood that the specific geometric layout of these is not limiting. For example, curved beam portions may also be used in opposition to the elongate cuboidal beam portions of the figures.

Furthermore, the above-described materials choices (e.g. SiO₂) should not be taken as limiting—any other materials with properties appropriate to each application may also be selected.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may have been made above to the use of embodiments of the invention in the context of optical lithography, it will be appreciated that the invention, where the context allows, is not limited to optical lithography and may be used in other applications, for example imprint lithography.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1-36. (canceled)

37. An assembly comprising:
a mirror; and
one or more deformable members, a first end of that defines a support portion and a second end of that is attached either directly or indirectly to the mirror;
wherein each of the one or more deformable members comprises a first actuator and a second actuator;
wherein the first and second actuators are independently addressable;
wherein actuation of the first actuator moves the mirror relative to the support portion in a first direction and wherein actuation of the second actuator moves the mirror relative to the support portion in a second direction that is opposite to the first direction;
wherein each deformable member comprises a structural frame configured to support an active portion of each of the first and second actuators, and
wherein each structural frame comprises an array of two or more generally mutually parallel beam portions, pairs of adjacent beam portions are connected together at one end, wherein each beam portion is only connected to one adjacent beam portion at any given end.

38. The assembly of claim 37, wherein at least one of the first and second actuators comprises at least one actuator portion, wherein each such actuator portion comprises: a flexible member and an active layer disposed on a surface of the flexible member and operable to distort the flexible member.

39. The assembly of claim 38, wherein the active layers of the actuator portions of the first and second actuators are disposed on the same side of the structural frame.

40. The assembly of claim 38, wherein each active layer is configurable in at least a first, nominal state and a second, actuated state.

41. The assembly of claim 38, wherein each active layer comprises a piezoelectric material.

42. The assembly of claim 37, wherein the assembly comprises a plurality of deformable members, the second end of at least two of the plurality of deformable members is attached to a different part of the mirror.

43. The assembly of claim 37, wherein the assembly comprises four deformable members.

44. The assembly of claim 43, wherein the four deformable members are arranged in a 4^{th} order rotationally symmetric layout.

45. The assembly of claim 37, wherein each deformable member attaches to the mirror by means of one or more pillars.

46. The assembly of claim 45, wherein each pillar is formed from a material with a thermal resistance that is high compared to a thermal resistance of the deformable member that it connects to the mirror.

47. A micromirror array comprising:
a substrate; and
a plurality of assemblies of claim 37;
wherein the support portion of each of the one or more deformable members of each of the plurality of assemblies are connected to the substrate.

48. A programmable illuminator comprising:
a micromirror array having a substrate and a plurality of assemblies of claim 37, wherein the support portion of each of the one or more deformable members of each of the plurality of assemblies are connected to the substrate;
a power supply; and
a control system, the control system operable to supply control signals using the power supply to the first and second actuators of the one or more deformable members of each of the plurality of assemblies so as to control the orientation of the mirrors of the plurality of assemblies.

49. The photolithography apparatus comprising the programmable illuminator comprising:
a micromirror array having a substrate and a plurality of assemblies of claim 37, wherein the support portion of each of the one or more deformable members of each of the plurality of assemblies are connected to the substrate;
a power supply; and
a control system, the control system operable to supply control signals using the power supply to the first and second actuators of the one or more deformable members of each of the plurality of assemblies so as to control the orientation of the mirrors of the plurality of assemblies.

50. An inspection and/or metrology apparatus comprising the programmable illuminator comprising:
a micromirror array having a substrate and a plurality of assemblies of claim 37, wherein the support portion of each of the one or more deformable members of each of the plurality of assemblies are connected to the substrate;
a power supply; and
a control system, the control system operable to supply control signals using the power supply to the first and second actuators of the one or more deformable members of each of the plurality of assemblies so as to control the orientation of the mirrors of the plurality of assemblies.

51. A method for forming an assembly, the method comprising:
providing a mirror; and
providing one or more deformable members, a first end of that defines a support portion, wherein the or each of the one or more deformable members comprises a first actuator and a second actuator and wherein the first and second actuators are independently addressable;
attaching a second end of each of the one or more deformable members to the mirror;
wherein actuation of the first actuator moves the mirror relative to the support portion in a first direction and wherein actuation of the second actuator moves the mirror relative to the support portion in a second direction that is opposite to the first direction;
wherein providing each of the one or more deformable members comprises:
forming a structural frame comprising two or more beam portions; and
depositing an active layer on a surface of at least two of the two or more beam portions; and
wherein the or each structural frame comprises an array of two or more generally mutually parallel beam portions, each pair of adjacent beam portions connected together at one end, wherein each beam portion is only connected to one adjacent beam portion at any given end.
